(19) United States
(12) Patent Application Publication
(10) Pub. No.: US 2003/0098750 A1
(43) Pub. Date: May 29, 2003

(54) Oscillator module and electronic apparatus using the same

(75) Inventors: Hisao Hayafuji, Omihachiman-shi (JP); Shinji Goma, Yasu-gun (JP)

Correspondence Address: OSTROLENK FABER GERB & SOFFEN, 1180 AVENUE OF THE AMERICAS, NEW YORK, NY, 100368403

(73) Assignee: Murata Manufacturing Co., Ltd.

(21) Appl. No.: 10/273,752

(22) Filed: Oct. 17, 2002

(30) Foreign Application Priority Data
Nov. 26, 2001 (JP) 2001-360035

(51) Int. Cl. H03B 1/00

(52) U.S. Cl. 331/100

(57) ABSTRACT

An oscillator module includes a circuit board having a plurality of side-face ground terminals, a DC-voltage input section formed on the circuit board, and a high-frequency oscillating circuit section formed on the circuit board. In the oscillator module, the ground of the DC-voltage input section and the ground of the high-frequency oscillating circuit section are connected to different side-face ground terminals.

### BACKGROUND OF THE INVENTION

1. Field of the Invention

The present invention relates to oscillator modules and electronic apparatuses using the same, and more specifically, to an oscillator module used, for example, as a local oscillator of a portable telephone, and an electronic apparatus using the oscillator module.

2. Description of the Related Art

FIG. 6 is a perspective view of a conventional oscillator module. In FIG. 6, an oscillator module 1 is formed of a circuit board 2, circuit components (not shown) mounted on and in the circuit board 2, and a metal cover 3 covering the upper side of the circuit board 2. At side faces of the circuit board 2, a plurality of side-face ground terminals G1 (not shown), G2, G3, and G4 (not shown), a power-source terminal Vb, an output terminal Po, a control-voltage input terminal Vc (not shown) are formed. Four protrusions are formed at respective side faces of the cover 3, and they are soldered to the side-face ground terminals G1 to G4, respectively. These side-face ground terminals G1 to G4 are connected by soldering to a ground electrode formed on a printed circuit board of a portable telephone when, for example, the oscillator module 1 is mounted on the printed circuit board.

FIG. 7 shows a bottom view of the circuit board 2. The bottom surface of the circuit board 2, which also serves as the bottom surface of the oscillator module 1, has a bottom-surface ground electrode Ga at almost its entire surface, and the four side-face ground terminals G1 to G4 are all connected to the bottom-surface ground electrode Ga. Gaps for preventing short-circuits are provided between the power-source terminal Vb, the output terminal Po, and the control-voltage input terminal Vc formed on side-faces of the circuit board 2, and the bottom-surface ground terminal Ga. For convenience in manufacturing the circuit board 2, an unconnected terminal NC is also provided.

FIG. 8 is a circuit diagram of the oscillator module 1. In FIG. 8, the oscillator module 1 is formed of transistors Q1 and Q2, resistors R1 to R4, capacitors C1 to C11, inductors L1 to L4, and a varactor diode VD, which is a voltage-controlled variable capacitive device. The inductors L1 to L4 are formed of microstriplines or striplines formed on or in the circuit board 2.

The collector of the transistor Q2 is grounded through the capacitor C4 with respect to high-frequency signals, so that the transistor Q2 forms a negative-resistance circuit for oscillation. The inductor L4, the capacitors C8 to C10, and the varactor diode VD form a resonant circuit for oscillation. The control-voltage input terminal Vc applies a DC voltage to the cathode of the varactor diode VD. The inductor L1 serving as a choke device and the capacitor C11 serving as a bypass capacitor are provided so that unnecessary high-frequency signals (noise) are not input from the outside to the varactor diode VD through the control-voltage input terminal Vc. The inductor L3 and the capacitor C5 are provided in order to set the impedance between the emitter of the transistor Q2 and the ground to an appropriate value.

The transistor Q1 is provided for buffer amplification for an oscillation signal output by the transistor Q2. The emitter of the transistor Q1 is grounded through the capacitor C4 for high-frequency signals. The oscillation signal is input to the base of the transistor Q1 through the capacitor C6, and is output from the collector to the output terminal Po through a matching circuit formed of the capacitors C2 and C3. The power-source terminal Vb is used for supplying a voltage and current to the two transistors Q1 and Q2, which are connected in cascade. The inductor L2 serving as a choke device and the capacitor C1 serving as a bypass capacitor are provided so that unnecessary high-frequency signals (noise) are not input from the outside through the power-source terminal Vb. The resistors R1 to R4 are provided to cause appropriate bias current to flow into the two transistors Q1 and Q2.

In the oscillator module 1, structured in this way, a DC voltage is input from the power-source terminal Vb. Ideally, there exists no high-frequency oscillation signal at the connection point of the inductor L2 and the capacitor C1. The section formed of the inductor L2 and the capacitor C1 and where no high-frequency oscillation signal ideally exists is called the DC-voltage input section 5.

In the oscillator module 1, a section formed of the transistor Q2, the capacitor C4 for collector grounding, and the above-described resonant circuit and where a high-frequency oscillation signal operationally exists to determine an oscillation frequency or to perform positive-feedback amplification operation is called a high-frequency oscillating circuit section 6. Since the varactor diode VD serves as a main section of the resonant circuit, it belongs to the high-frequency oscillating circuit section 6.

In the oscillator module 1, a DC control voltage is input from the control-voltage input terminal Vc. Ideally, there exists no high-frequency oscillating signal at the connection point of the inductor L1 and the capacitor C11. A portion formed of the inductor L1 and the capacitor C11 and where no high-frequency oscillating signal ideally exists is called a control-voltage input section 7.

In the oscillator module 1, a matching circuit formed of the transistor Q1 and the capacitors C2 and C3 is a portion where a high-frequency oscillation signal operationally exists but which does not have a transmitting function and is different from the high-frequency oscillating circuit section 6, and is called a buffer amplification circuit section 8.

In the oscillator module 1, having the above-described circuit structure, one end (hereinafter called a ground end) of each of the inductor L3, the resistor R3, the capacitor C9, and the inductor L4, is connected to ground via the side-face ground terminal G1 formed at a side face of the circuit board 2. In FIG. 8, side-face ground terminals are indicated by circles. Ground ends of the capacitors C5 and C1 are connected to the side-face ground terminal G2. A ground end of the capacitor C11 and the anode of the varactor diode VD are connected to the side-face ground terminal G3. Ground ends of the capacitors C4 and C3 are connected to the side-face ground terminal G4. Consequently, each ground end of each circuit component of the high-frequency oscillating circuit section 6 is connected to one of the four side-face ground terminals G1, G2, G3, and G4; the ground of the control-voltage input section 7 is connected to the side-face ground terminal G3; the ground of the DC-voltage input section 5 is connected to the side-face ground terminal G2; and the ground of the buffer amplification circuit section 8 is connected to the side-face ground terminal G4.

As described above, in the conventional oscillator module 1, the DC-voltage input section 5, the high-frequency oscillating circuit section 6, the control-voltage input section 7, and the buffer amplification circuit section 8 are each connected to one or more of the side-face ground terminals G1, G2, G3, and G4. Two of the sections may be connected to the same ground terminal because, for example, they are close each other, and there is no rule for defining their relationships.

When the oscillator module 1, shown in FIG. 6 to FIG. 8, is mounted on a main printed circuit board of a portable telephone, for example, the ground of the printed circuit board does not have the same potential as each of the side-face ground terminals G1 to G4 of the oscillator module 1, in a strict sense. Strictly speaking, at high frequencies, since ground wiring itself has a parasitic inductor component, parasitic inductor components Z1 to Z4 are connected between the side-face ground terminals G1 to G4 and the ground of the printed circuit board, as shown in an equivalent circuit diagram of FIG. 9. Such parasitic inductor components are not substantially reduced even when the side-face ground terminals G1 to G4 are connected to each other through the bottom-surface ground electrode Ga, formed on the bottom surface of the circuit board 2.

In such a mounting condition, since the ground end of the capacitor C4, which should be ideally connected to the ground for grounding the transistor Q2 for high-frequency signals, is grounded through the parasitic inductor component Z2, and the other ground ends are also grounded through the corresponding parasitic inductor components. When the oscillator module 1 is mounted on the printed circuit board, grounding conditions vary depending on the respective location of each ground terminal, and it is possible for the fluctuation of the oscillation frequency to become large when the oscillator module 1 is mounted.

Simulations were carried out to determine the range of change of the oscillation frequency caused by a change in magnitude of the parasitic inductor components Z1 to Z4. When, for example, the oscillator module 1 oscillated at a frequency in a 1.6 GHz band, the oscillation frequency was 1,673 MHz when the parasitic inductor components had an inductance of 0 nH. However, the oscillation frequency was 1,663 MHz (reduced by 10 MHz) when the parasitic inductor components had an inductance of 0.02 nH, and the oscillation frequency was 1,624 MHz (reduced by 49 MHz) when the parasitic inductor components had an inductance of 0.10 nH.

It is assumed here that high-frequency noise is input to the oscillator module 1, for example, through the power-source terminal Vb in such a mounting condition. The high-frequency noise cannot pass through the inductor L2, but passes through the capacitor C1 and reaches the connection point of the capacitor C5 and the side-face ground terminal G4. Since the side-face ground terminal G4 is not directly connected to the ground due to the presence of the parasitic inductor component Z4, the high-frequency noise which has passed through to this point is input to the emitter of the transistor Q2 through the capacitor C5 (path u1). Therefore, it is possible for the high-frequency noise to have an adverse effect on the oscillation, so that, if the oscillator module is used, for example, for a digital portable telephone, the bit error rate (BER) of the portable telephone deteriorates.

If high-frequency noise is input from the output terminal Po, it is input to the collector of the transistor Q2 through the capacitors C2, C3, and C4 (path u2) for the same reason. If high-frequency noise is input from the control-voltage input terminal Vc, it is input to the anode of the varactor diode VD through the capacitor C11 (path u3). Also in these cases, it is possible for the high-frequency noise to have an adverse effect on the oscillation.

### SUMMARY OF THE INVENTION

The present invention has been made to solve the foregoing problems. The present invention provides an oscillator module which is less susceptible to the effect of external high-frequency noise when mounted on a printed circuit board, and an electronic apparatus using the oscillator module.

According to one aspect of the present invention, an oscillator module includes a circuit board having a plurality of side-face ground terminals; a DC-voltage input section formed on the circuit board; and a high-frequency oscillating circuit section formed on the circuit board, wherein the ground of the DC-voltage input section and the ground of the high-frequency oscillating circuit section are connected to different side-face ground terminals.

The oscillator module may be configured such that it further includes a buffer amplification circuit section formed on the circuit board, and the ground of the buffer amplification circuit section is connected to a side-face ground terminal different from the side-face ground terminal connected to the ground of the high-frequency oscillating circuit section.

In the oscillator module, the ground of the buffer amplification circuit section may be connected to a side-face ground terminal different from the side-face ground terminal connected to the ground of the DC-voltage input section.

The oscillator module may be configured such that it further includes a control-voltage input section formed on the circuit board; the high-frequency oscillating circuit section includes a voltage-controlled variable capacitive device; the control-voltage input section applies a control voltage to the voltage-controlled variable capacitive device; and the ground of the control-voltage input section is connected to a side-face ground terminal different from the side-face ground terminal connected to the ground of the high-frequency oscillating circuit section.

The oscillator module may further be configured with two or more of its side-face ground terminals on different respective side faces of the circuit board. This feature improves the isolation between the side-face ground terminals and further reduces the adverse effect of externally input high-frequency noise, and accordingly, when combined with the other disclosed features, is considered to be an advantageous aspect of the present invention.

With such a structure, an oscillator module according to the present invention reduces the fluctuation of the oscillation frequency which may occur when the oscillator module is mounted. In addition, the oscillator module is less susceptible to the adverse effect of high-frequency noise input from each terminal of the oscillator module.

According to another aspect of the present invention, an electronic apparatus includes an oscillator module as described above.

In an electronic apparatus according to the present invention, since an oscillator module according to the present invention is used, malfunctions are reduced.

Other features and advantages of the present invention will become apparent from the following description of embodiments of the invention which refers to the accompanying drawings.

### BRIEF DESCRIPTION OF THE DRAWINGS

FIG. 1 is a circuit diagram of an oscillator module according to an embodiment of the present invention.

FIG. 2 is an equivalent circuit diagram of the oscillator module shown in FIG. 1.

FIG. 3 is an equivalent circuit diagram of an oscillator module according to another embodiment of the present invention.

FIG. 4 is an equivalent circuit diagram of an oscillator module according to still another embodiment of the present invention.

FIG. 5 is a perspective view of an electronic apparatus according to an embodiment of the present invention.

FIG. 6 is a perspective view of a conventional oscillator module.

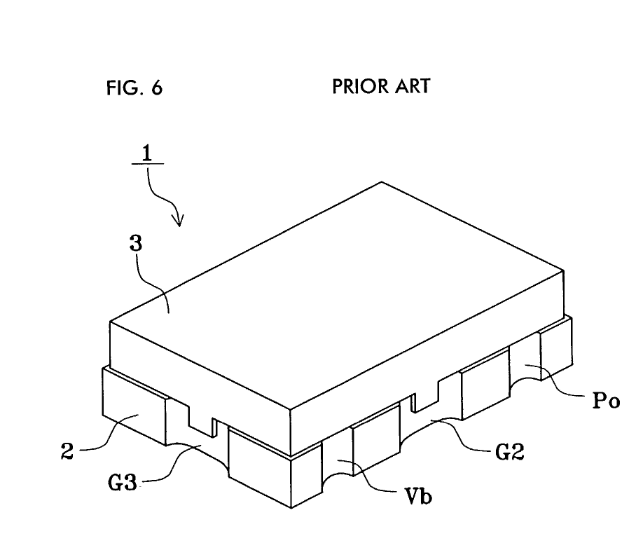

FIG. 7 is a bottom view of the oscillator module shown in FIG. 6.

FIG. 8 is a circuit diagram of the oscillator module shown in FIG. 6.

FIG. 9 is an equivalent circuit diagram of the oscillator module shown in FIG. 6.

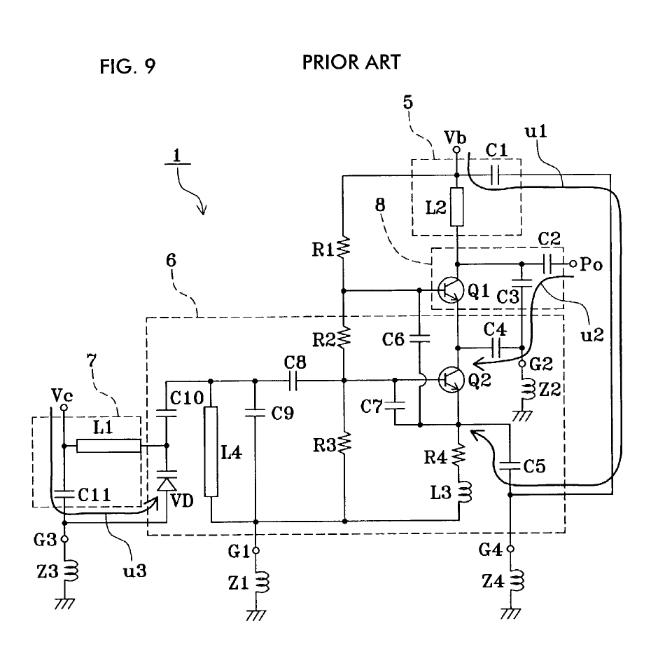

### DESCRIPTION OF EMBODIMENTS OF THE INVENTION

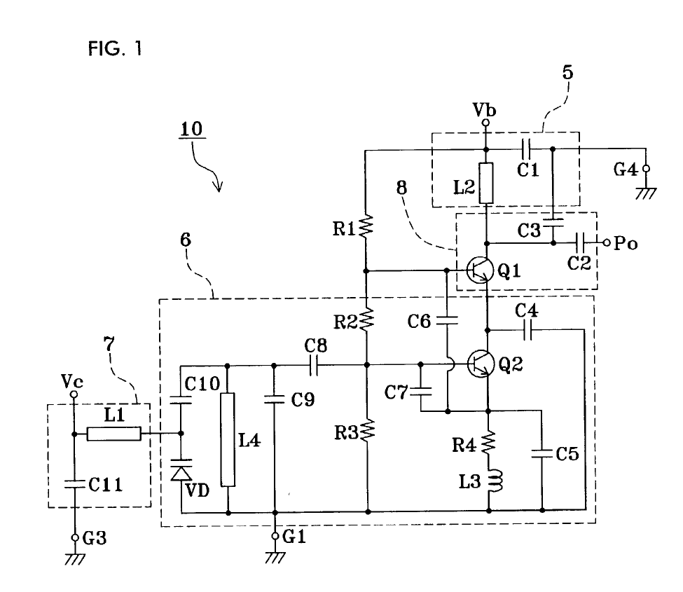

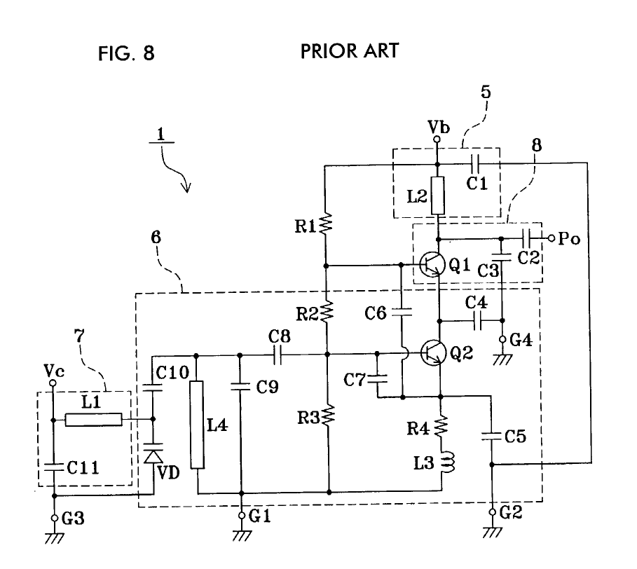

FIG. 1 is a circuit diagram of an oscillator module according to an embodiment of the present invention. In FIG. 1, the same symbols as those used in FIG. 8 are assigned to the same or similar portions as or to those shown in FIG. 8, and descriptions thereof are omitted.

An oscillator module 10 shown in FIG. 1 has the same circuit components and same circuit connection as the conventional oscillator module 1, but differs only in the connections between the devices required to be grounded and their respective side-face ground terminals. More specifically, a ground end of a capacitor C4, that of a capacitor C5, that of an inductor L3, that of a resistor R3, that of a capacitor C9, that of an inductor L4, and the anode of a varactor diode VD are connected to a side-face ground terminal G1. A ground end of a capacitor C11 is connected to a side-face ground terminal G3. A ground end of a capacitor C1 and that of a capacitor C3 are connected to a side-face ground terminal G4. Nothing is connected to a side-face ground terminal G2.

With such a structure, in the oscillator module 10, all ground points of a high-frequency oscillating circuit section 6 are connected to the side-face ground terminal G1, the ground point of a control-voltage input section 7 is connected to the side-face ground terminal G3, and the ground point of a DC-voltage input section 5 and that of a buffer amplification circuit section 8 are connected to the side-face ground terminal G4.

In other words, the ground point of the DC-voltage input section 5 and those of the high-frequency oscillating circuit section 6 are connected to different side-face ground terminals. In addition, the ground point of the control-voltage input section 7 is connected to the side-face ground terminal different from that connected to the ground points of the high-frequency oscillating circuit section 6. Further, the ground point of the buffer amplification circuit section 8 is connected to the side-face ground terminal different from that connected to the ground points of the high-frequency oscillating circuit section 6. The ground point of the buffer amplification circuit section 8 and that of the DC-voltage input section 5 are connected to the same side-face ground terminal G4.

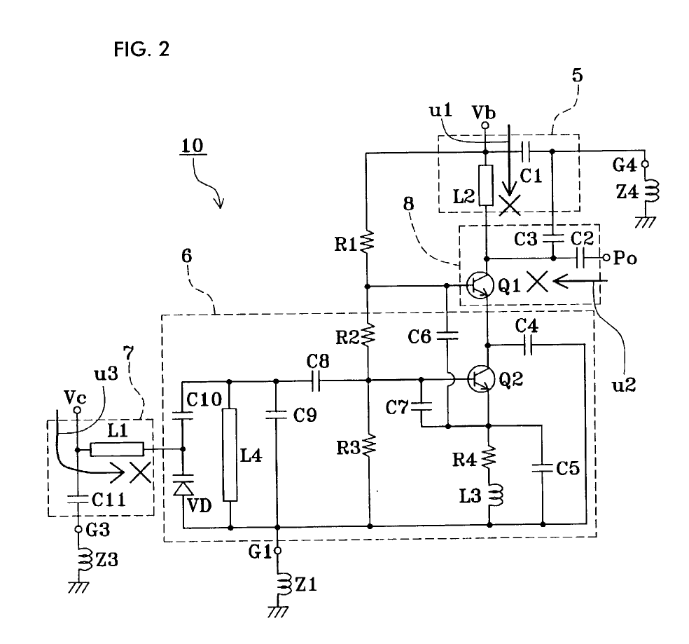

It is assumed here that the oscillator module 10 having the above structure is mounted on a main printed circuit board of a portable telephone. In this case, in the same way as for the conventional oscillator module 1, strictly speaking, parasitic inductor components Z1, Z3, and Z4 are connected between the side-face ground terminals G1, G3, and G4, and the ground of the printed circuit board, respectively, as shown in an equivalent circuit diagram of FIG. 2.

In this case, since all the ground points of the high-frequency oscillating circuit section 6 are connected to the side-face ground terminal G1, the fluctuation of the oscillation frequency, obtained when the oscillator module 10 is mounted on the printed circuit board is not as great as that of the oscillation frequency of the conventional oscillator module 1.

It was found by simulation, for checking the range of changes of the oscillation frequency caused by the magnitudes of the parasitic inductor components Z1, Z3, and Z4, that when the oscillator module 10 oscillated at a frequency in a 1.6 GHz zone in the same way as the conventional oscillator module 1, the oscillation frequency was 1,673 MHz when the parasitic inductor components had an inductance of 0 nH, the oscillation frequency was 1,672 MHz (reduced by 1 MHz) when the parasitic inductor components had an inductance of 0.02 nH, and the oscillation frequency was 1,671 MHz (reduced by 1 MHz) when the parasitic inductor component had an inductance of 0.10 nH. This means that the changes of the oscillation frequency caused by the parasitic inductor components are much smaller.

It is assumed that high-frequency noise is input, for example, to a power-source terminal Vb in the oscillator module 10 mounted as described above, in the same way as for the conventional oscillator module. The high-frequency noise passes through the capacitor C1 and the capacitor C3 to the collector of a transistor Q1, but the high-frequency noise does not go further into the high-frequency oscillating circuit section 6 (path u1) because the ground point of the DC-voltage input section 5 and that of the buffer amplification circuit section 8 are connected to the side-face ground terminal G4, which is different from the side-face ground terminal to which the ground points of the high-frequency oscillating circuit section 6 are connected. Therefore, the high-frequency noise does not have an adverse effect on the oscillation. The BER of the portable telephone on which the oscillator module 10 is mounted is not reduced.

Also when high-frequency noise is input to an output terminal Po, the high-frequency noise does not go into the high-frequency oscillating circuit section 6 (path u2) for the same reason. In addition, also when high-frequency noise is input to a control-voltage input terminal Vc, the high-frequency noise does not go further into the high-frequency oscillating circuit section 6 (path u3) because the ground point of the control-voltage input section 7 is connected to the side-face ground terminal G3, which is different from the side-face ground terminal to which the ground points of the high-frequency oscillating circuit section 6 are connected.

As described above, since the ground points of the high-frequency oscillating circuit section 6 are connected to the side-face ground terminal, which is different from the side-face ground terminals to which the ground point of the DC-voltage input section 5, that of the control-voltage input section 7, and that of the buffer amplification circuit section 8 are connected in the oscillator module 10 of the present invention, the change of the frequency, obtained when the oscillator module 10 is mounted is small, and a reduction in the BER of the portable telephone on which the oscillator module 10 is mounted, caused by an adverse effect of high-frequency noise externally input, does not occur.

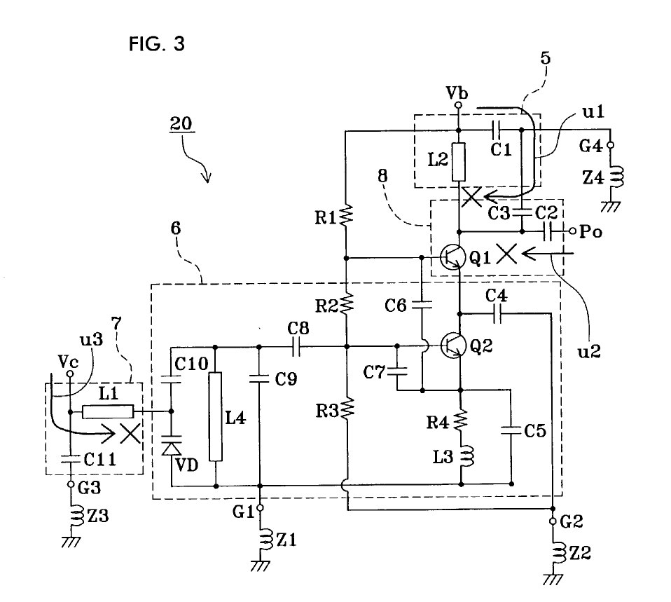

FIG. 3 is an equivalent circuit diagram of an oscillator module according to another embodiment of the present invention. In FIG. 3, the same symbols as those used in FIG. 2 are assigned to the same or similar portions as or to those shown in FIG. 2, and descriptions thereof are omitted. In this embodiment, only the equivalent circuit diagram is shown. A circuit diagram, such as that for the conventional case, is omitted.

In an oscillator module 20 shown in FIG. 3, a ground end of a capacitor C5, that of an inductor L3, that of a capacitor C9, that of an inductor L4, and the anode of a varactor diode VD are connected to a side-face ground terminal G1. A ground end of a capacitor C4 and that of a resistor R3 are connected to a side-face ground terminal G2. In other words, the ground points of a high-frequency oscillating circuit section 6 are divided into two groups and connected to the side-face ground terminals G1 and G2. This is the only difference from the oscillator module 10 shown in FIG. 2. As in the oscillator module of FIG. 2, the ground points of the high-frequency oscillating circuit section 6 are connected to side-face ground terminals different from those connected to the ground points of a DC-voltage input section 5, a control-voltage input section 7, and a buffer amplification circuit section 8.

In this case, since the ground points of the high-frequency oscillating circuit section 6 are connected to the two side-face ground terminals G1 and G2, the oscillator module 20 has great flexibility in how ground wirings can be arranged at the high-frequency oscillating circuit section 6, compared with the oscillator module 10, but the fluctuation of the oscillation frequency, obtained when the oscillator module 20 is mounted on a printed circuit board, is not as large as that in the conventional oscillator module 1.

It was found by simulation, for checking the range of changes of the oscillation frequency caused by the magnitudes of parasitic inductor components Z1 to Z4, that when the oscillator module 20 oscillated at a frequency in a 1.6 GHz band in the same way as the conventional oscillator module 1, the oscillation frequency was 1,673 MHz when the parasitic inductor components had an inductance of 0 nH, the oscillation frequency was 1,672 MHz (reduced by 1 MHz) when the parasitic inductor components had an inductance of 0.02 nH, and the oscillation frequency was 1,669 MHz (reduced by 4 MHz) when the parasitic inductor component had an inductance of 0.10 nH. This means that the changes of the oscillation frequency caused by the parasitic inductor components are much smaller although the changes are not as small as those of the oscillator module 10.

Also in the oscillator module 20 having the above structure, in the same way as in the oscillator module 10, high-frequency noise input to each terminal does not go into the high-frequency oscillating circuit section 6. Therefore a reduction in the BER of a portable telephone on which the oscillator module 20 is mounted, caused by an adverse effect of the high-frequency noise externally input, does not occur.

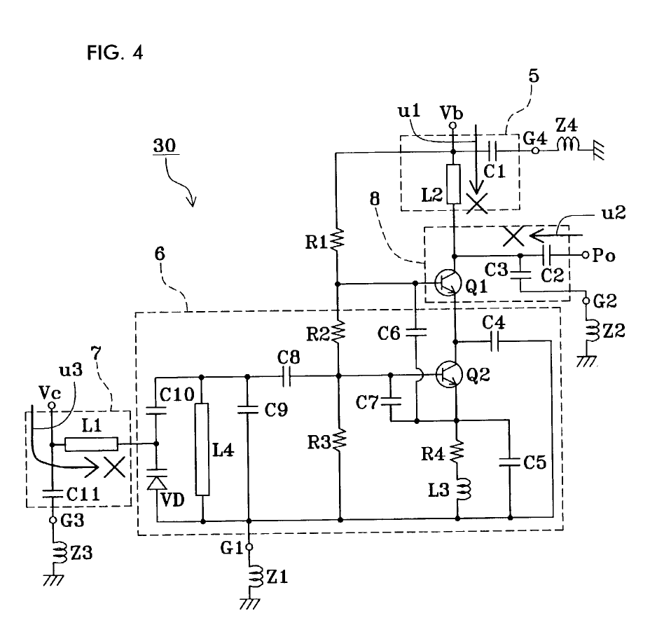

FIG. 4 is an equivalent circuit diagram of an oscillator module according to still another embodiment of the present invention. In FIG. 4, the same symbols as those used in FIG. 2 are assigned to the same or similar portions as or to those shown in FIG. 2, and descriptions thereof are omitted. Also in this embodiment, only the equivalent circuit diagram is shown. A circuit diagram, such as that for the conventional case, is omitted.

In an oscillator module 30 shown in FIG. 4, a ground end of a capacitor C3 is connected to a side-face ground terminal G2. Only a ground end of a capacitor C1 is connected to a side-face ground terminal G4. In other words, the ground point of a buffer amplification circuit section 8 is connected to the side-face ground terminal G2, which is different from not only a side-face ground terminal connected to the ground points of a high-frequency oscillating circuit section 6 but also a side-face ground terminal connected to the ground point of a DC-voltage input section 5.

Since the oscillator module 30 having the above-described structure has the structure in which the ground point of the DC-voltage input section 5 and that of the buffer amplification circuit section 8 are connected to different side-face ground terminals, in addition to the structure of the oscillator module 10, high-frequency noise input, for example, to a power-source terminal Vb does not go into the buffer amplification circuit section 8. If the oscillator module 30 did not have the above-described structure externally input high-frequency noise might have an adverse effect on the buffer amplification circuit section 8, such as modulating an oscillation signal, although not so strong as the adverse effect of external noise on the high-frequency oscillating circuit section 6. With the above-described structure, however, such an adverse effect is prevented.

In each of the above-described embodiments, the high-frequency circuit section 6 includes the varactor diode for variably changing the oscillation frequency, and the control-voltage input section 7 for applying a control voltage to the varactor diode is provided to form the voltage-controlled oscillator module. The invention is also usable with a fixed-oscillation-frequency oscillator module having no oscillation-frequency-changing function. In this case, the same effects and advantages as those obtained when the control-voltage input section 7 is provided are obtained.

The buffer amplification circuit section 8 is not necessarily provided. In this case, the same effects and advantages as those obtained when the buffer amplification circuit section 8 is provided are obtained.

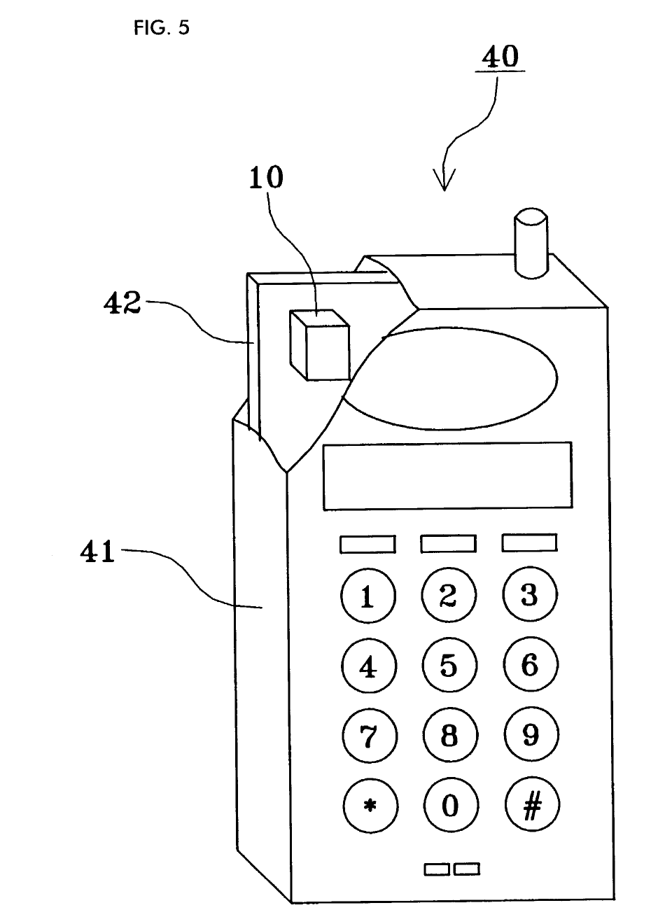

FIG. 5 is a perspective view of an electronic apparatus according to an embodiment of the present invention. In FIG. 5, a portable telephone 40, which is one type of electronic apparatus, includes a housing 41, a printed circuit board 42 disposed therein, and the oscillator module 10 according to the present invention, mounted on the printed circuit board 42.

Since the oscillator module 10 according to the present invention is used in the portable telephone 40 having the above-described structure, malfunctions are reduced. When the portable telephone 40 is of a digital type, the BER thereof is reduced.

The portable telephone in FIG. 5 is taken as an example of an electronic apparatus. The electronic apparatus is not limited to this portable telephone. The invention includes any electronic apparatus which uses an oscillator module according to any embodiment of the present invention.

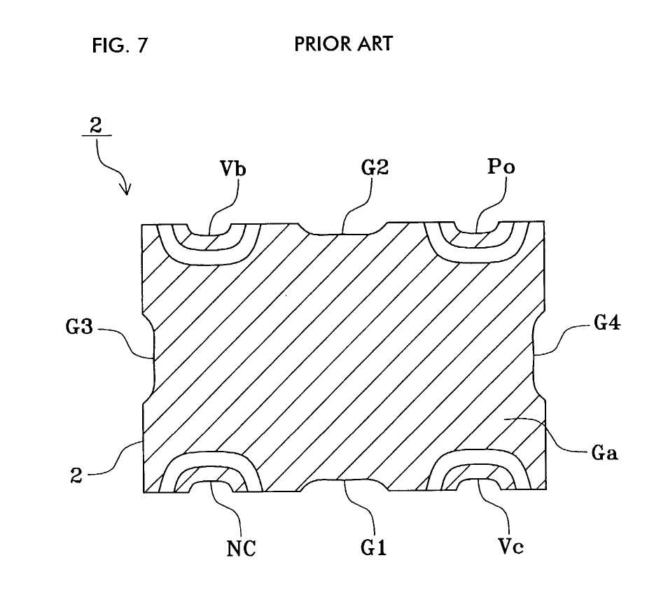

In each of the foregoing embodiments, as in the prior art example of FIG. 7, each of the side-face ground terminals G1-G4 may advantageously be disposed on a different respective side face of the circuit board. Even more advantageously, each of the side-face ground terminals may be disposed at the center of the corresponding side-face. This feature improves the isolation between the side-face ground terminals and further reduces the adverse effect of externally input high-frequency noise.

Although the present invention has been described in relation to particular embodiments thereof, many other variations and modifications and other uses will become apparent to those skilled in the art. Therefore, the present invention is not limited by the specific disclosure herein.

What is claimed is:

1. An oscillator module comprising:
a circuit board having a plurality of side-face ground terminals;
a DC-voltage input section formed on the circuit board and having a ground; and
a high-frequency oscillating circuit section formed on the circuit board and having a ground, p1 wherein the ground of the DC-voltage input section and the ground of the high-frequency oscillating circuit section are connected to different side-face ground terminals.

2. An oscillator module according to claim 1, wherein said plurality of side-face ground terminals are formed on different respective side faces of said circuit board.

3. An oscillator module according to claim 1, further comprising a buffer amplification circuit section formed on the circuit board and having a ground,
wherein the ground of the buffer amplification circuit section is connected to a side-face ground terminal different from the side-face ground terminal connected to the ground of the high-frequency oscillating circuit section.

4. An oscillator module according to claim 3, wherein said plurality of side-face ground terminals are formed on different respective side faces of said circuit board.

5. An oscillator module according to claim 3, wherein the ground of the buffer amplification circuit section is connected to a side-face ground terminal different from the side-face ground terminal connected to the ground of the DC-voltage input section.

6. An oscillator module according to claim 5, wherein said plurality of side-face ground terminals are formed on different respective side faces of said circuit board.

7. An oscillator module according to claim 1, further comprising a buffer amplification circuit section formed on the circuit board and having a ground,
wherein the ground of the buffer amplification circuit section is connected to a side-face ground terminal different from the side-face ground terminal connected to the ground of the DC-voltage input section.

8. An oscillator module according to claim 7, wherein said plurality of side-face ground terminals are formed on different respective side faces of said circuit board.

9. An oscillator module according to claim 1, further comprising a control-voltage input section formed on the circuit board and having a ground,
wherein the high-frequency oscillating circuit section comprises a voltage-controlled variable capacitive device;
the control-voltage input section applies a control voltage to the voltage-controlled variable capacitive device; and
the ground of the control-voltage input section is connected to a side-face ground terminal different from the side-face ground terminal connected to the ground of the high-frequency oscillating circuit section.

10. An oscillator module according to claim 9, wherein said plurality of side-face ground terminals are formed on different respective side faces of said circuit board.

11. An electronic apparatus comprising the oscillator module described in claim 1.

12. An electronic apparatus according to claim 11, wherein said plurality of side-face ground terminals are formed on different respective side faces of said circuit board.
